(19) United States
(12) Patent Application Publication
(10) Pub. No.: US 2021/0075186 A1
(43) Pub. Date: Mar. 11, 2021

(54) LASER DIODE MODULE, TRANSMITTER, RANGING DEVICE AND ELECTRONIC DEVICE

(71) Applicant: SZ DJI TECHNOLOGY CO., LTD., Shenzhen (CN)

(72) Inventors: Guoguang ZHENG, Shenzhen (CN); Xiang LIU, Shenzhen (CN); Jiangbo CHEN, Shenzhen (CN); Xiaoping HONG, Shenzhen (CN)

(21) Appl. No.: 16/949,405

(22) Filed: Oct. 28, 2020

Related U.S. Application Data
(63) Continuation of application No. PCT/CN2018/085125, filed on Apr. 28, 2018.

(51) Int. Cl. H01S 5/022; H01S 5/042; H01S 5/024

(52) U.S. Cl. CPC H01S 5/02248; G01S 7/4814; H01S 5/02469; H01S 5/04256

(57) ABSTRACT

The present disclosure provides a laser diode module. The laser diode module includes a substrate including a first surface and a second surface opposite to each other; a cover disposed on the first surface of the substrate, and an accommodation space being formed between the substrate and the cover; and a laser diode die disposed in the accommodation space.

### CROSS-REFERENCE TO RELATED APPLICATION

This application is a continuation of International Application No. PCT/CN2018/085125, filed on Apr. 28, 2018, the entire content of which is incorporated herein by reference.

### TECHNICAL FIELD

The present disclosure relates to the field of integrated circuit and, more specifically, to a laser diode module, a transmitter, a ranging device, and an electronic device.

### BACKGROUND

In the transmitter circuits, the transmitter commonly uses in-line packaging. The use of in-line package is mainly to address the heat dissipation issues of the transmitter, or because in-line packaging is a commonly used process in the field. A laser diode will generate a relatively large amount of heat at the time of emission, and this heat needs to be dissipated to a good thermal conductor, such as a copper block. The in-line package provides a better heat dissipation structure for heat dissipation, such as its metal shell and metal pins.

Although in-line packaging is widely used, it needs further improvements. More specifically, the distributed inductance of an in-line package is relatively large, and the response to the fast pulse drive signal would be slower, which causes certain limitations on the fast narrow pulse signal drive.

Therefore, in order to improve the detection and measurement accuracy and sensitivity, the current package needs to be improved.

### SUMMARY

One aspect of the present disclosure provides a laser diode module. The laser diode module includes a substrate including a first surface and a second surface opposite to each other; a cover disposed on the first surface of the substrate, and an accommodation space being formed between the substrate and the cover; and a laser diode die disposed in the accommodation space.

### BRIEF DESCRIPTION OF THE DRAWINGS

FIG. 1 is a schematic diagram of a structure of a laser diode in a laser diode module according to an embodiment of the present disclosure.

FIG. 2 is a cross-sectional view of the laser diode of FIG. 1 along a B-B direction.

FIG. 3A is a schematic structural diagram of the laser diode module according to an embodiment of the present disclosure.

FIG. 3B is a cross-sectional view of the laser diode module of FIG. 3A along an A-A direction.

FIGS. 3C-3E are cross-sectional views of the laser diode module according to other embodiments of the present disclosure.

FIG. 4A is a schematic structural diagram of the laser diode module according to another embodiment of the present disclosure.

FIG. 4B is a cross-sectional view of the laser diode module of FIG. 4A along the A-A direction.

FIG. 4C is a top view of the laser diode module according to an embodiment of the present disclosure.

FIG. 4D is a cross-sectional view of the laser diode module of FIG. 4C.

FIG. 4E is a top view of the laser diode module according to another embodiment of the present disclosure.

FIG. 4F is a side view of the laser diode module according to yet another embodiment of the present disclosure.

FIGS. 5A-5B are schematic diagrams of a laser diode manufacturing process included in a laser diode module according to an embodiment of the present disclosure.

FIG. 5C is a schematic diagram of a structure of the laser diode included in the laser diode module before cutting according to an embodiment of the present disclosure.

FIG. 5D is a schematic diagram of the structure of the laser diode included in the laser diode module after cutting according to an embodiment of the present disclosure.

FIGS. 6A-6D are schematic structural diagrams of the laser diode module according to three other embodiments of the present disclosure.

FIGS. 7A-7F are schematic diagrams of the structure of a substrate and an outer cover in the laser diode module according to an embodiment to the present disclosure.

FIG. 8 is a schematic diagram of a structure of a laser ranging device according to an embodiment of the present disclosure.

FIG. 9 is a schematic diagram of a structure of a detection device according to an embodiment of the present disclosure.

### DETAILED DESCRIPTION OF THE EMBODIMENTS

In order to make the objectives, technical solutions, and advantages of the present disclosure clear, the technical solutions in the embodiments of the present disclosure will be described below with reference to the drawings. It will be appreciated that the described embodiments are some rather than all of the embodiments of the present disclosure. Other embodiments conceived by those having ordinary skills in the art on the basis of the described embodiments without inventive efforts should fall within the scope of the present disclosure.

The present disclosure may be implemented in various forms and is limited to the embodiments set forth herein. The disclosed embodiments may enable the present disclosure to be thorough and complete, and may fully convey the scope of the present disclosure to those skilled in the art.

The terms used herein are for the purpose of describing the detailed embodiments and are not intended to limit the scope of the present disclosure. The singular forms of “a”, “one”, and “the” may be intended to include plural forms unless otherwise clearly specified by the context. The terms of “composition” and/or “comprising” may be used to determine the presence of the features, integers, steps, operations, components and/or units, but may not exclude the presence or addition of one or more of other features, integers, steps, operations, components, units, and groups. The term “and/or” may include any and all combinations of the related items.

To fully understand the present disclosure, detailed structures and steps are set forth in the following descriptions to explain the technical solutions of the present disclosure. The optional embodiments of the present disclosure are described in detail below, but the present disclosure may have other embodiments in addition to the detailed description.

As described above, in transmitter circuits, the most commonly used transmitter package is the in-line package. In the in-line package structure, the laser diode is directly connected to a circuit board through a metal wire. More specifically, the distributed inductance of the in-line package is relatively large, and the response to the fast pulse drive signal will be slower, which causes limitations on the fast narrow pulse signal drive.

In the laser and laser ranging circuits, in compliance with safety regulations, the laser energy emitted each time has a certain limit. In order to improve the accuracy, the larger the laser power emitted each time the better. More emitted power means that the reflected laser intensity will be stronger, and the signal received at the receiving end will be stronger. In other words, longer distances can be measured using the same circuit and under the same optical conditions.

In order to balance the issue of emission power and safety regulations, the emitted pulse signal can be narrowed, that is, a certain amount of laser energy can be concentrated in a shorter amount of time to emit, such that both the safety regulations and the emission power requirements are satisfied. In order to narrow the pulse signal, the distributed inductance on the laser diode can be a challenge. The narrower the pulse, the greater the proportion of energy lost in the distributed inductance, which is an obstacle when increasing the emission power.

In addition, the distributed inductance on the laser diode package also has a certain stretching effect on the pulse signal. When the laser diode drive is turned on, the inductor will start to store energy. During this time, the laser diode's emission power will decrease. After the laser diode drive is turned off, this part of the inductance parameter will start to discharge, while the laser diode is still in the working state. At this time, the distributed inductance will play a role in stretching by dispersing and widening the original narrow pulse signal into a relatively wide pulse signal, which can become an obstacle when increasing the emission power.

The present disclosure provides a laser diode module. The laser diode module provided by the present disclosure will be described in detail below with reference to the accompanying drawings.

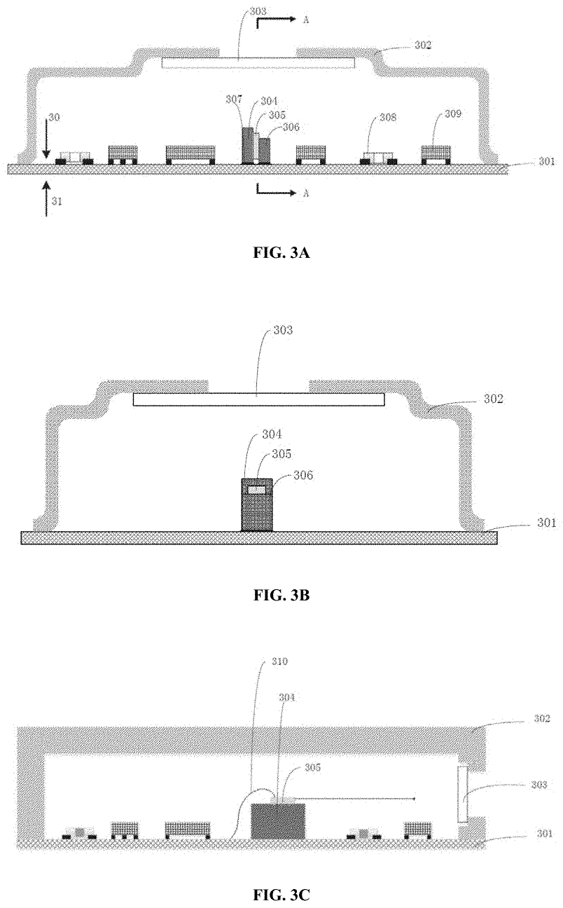

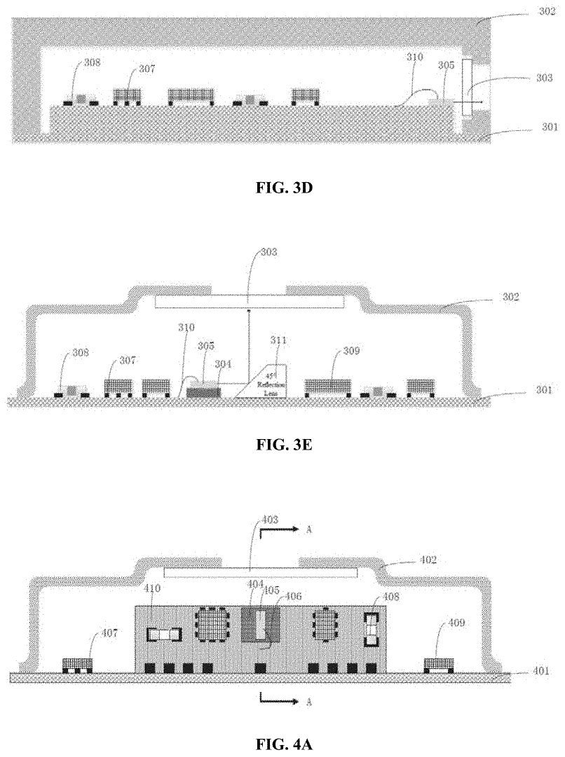

As shown in FIG. 3A, the laser diode module includes a substrate 301 including a first surface 30 and a second surface 31 opposite to each other; a cover disposed on the first surface of the substrate, and an accommodation space is formed between the substrate and the cover; and a laser diode die 305 disposed in the accommodation space.

In some embodiments, the module further includes a driver chip 309 for controlling the emission of the laser diode die, and the driver chip can be disposed in the accommodation space. In this embodiment, the driver chip 309 that controls the emission of the laser diode die and the laser diode die are directly packaged together, and both are packaged in the accommodation space formed between the substrate and the cover. By using the above setting, the inductance between the in-line laser diode and the drive circuit next to the laser diode and the distributed inductance on the line in the conventional in-line package can be eliminated. Therefore, the distributed inductance of the module can be reduced, and high-power laser emission and narrow pulse laser driving can be realized.

In some embodiments, in the module, the laser diode die can be placed as close to the driver chip as possible. The smaller the distance between the laser diode die and the driving chip, the more effective the distributed inductance can be reduced. By using this setting, the loss of the distributed inductance of the emitting module can be reduced, such that it is easier to realize high-power laser emission. Further, the reduction of the distributed inductance also makes the narrow pulse laser driving possible.

In some embodiments, the laser diode die 305 and the driver chip 309 may be directly mounted on the first surface of the substrate. In the present disclosure, the conventional in-line package can be improved by mounting to reduce the distributed inductance on the package in-line pins and further reduce the distributed inductance on the line, which is easier to realize high-power laser emission and narrow pulse laser driving.

In some embodiments, it is also possible to directly mount the laser diode die 305 on the first surface of the substrate, and simultaneously mount the driver chip 309 directly on the second surface of the substrate. Although the laser diode die 305 and the driver chip 309 are not disposed on the same surface, the distance between the laser diode die 305 and the driver chip 309 may be sufficiently close. Therefore, the inductance between the in-line laser diode and the drive circuit next to the laser diode and the distributed inductance on the line in conventional in-line package can be eliminated. Thereby reducing the distributed inductance of the packaged module, and realizing high-power laser emission and narrow pulse laser driving.

Of course, as a modification of this embodiment, the laser diode die may also be directly mounted on the first surface of the substrate. At the same time, a part of the driver chip may be mounted on the first surface, and another part of the driver chip may be mounted on the second surface. By using this setting, the area of the substrate can be further reduced, the second surface can be used more effectively, and the degree of integration of the packaged module can be further improved.

In a specific embodiment of the present disclosure, the packaged module may further include a switch chip, and the switch chip may also be disposed in the accommodation space. The switch chip may include a switch circuit, and the switch circuit can be used to control the laser diode die to emit laser light under the drive of the drive circuit.

In some embodiments, the laser diode die 305 may be a bare die, that is, a small piece of circuited “die” cut from a wafer, which can be mounted on the substrate 301 by means of die bond. Die bond may refers to the process of bonding the chip to a designed area of the substrate through glue, generally a conductive glue or an insulating glue, to form a thermal path or an electrical path to provide conditions for the subsequent wire bonding. In this embodiment, the laser diode die 305 is mounted on the substrate 301 through a silver paste or other soldering materials (e.g., a conductive glue) 307.

In some embodiments, the substrate 301 may be various types of substrates, such as a PCB substrate, a ceramic substrate, etc. The structure and material of the substrate will be described in further detail in the following descriptions.

In some embodiments, the cover is not limited to a certain structure. The cover may be at least partially provided with a light-transmitting area, and the emitted light of the laser diode die may be emitted through the light-transmitting area.

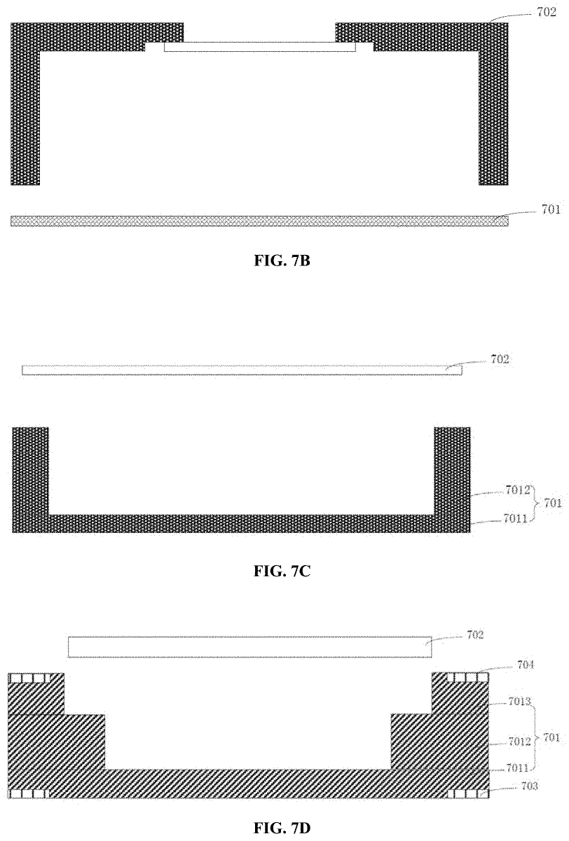

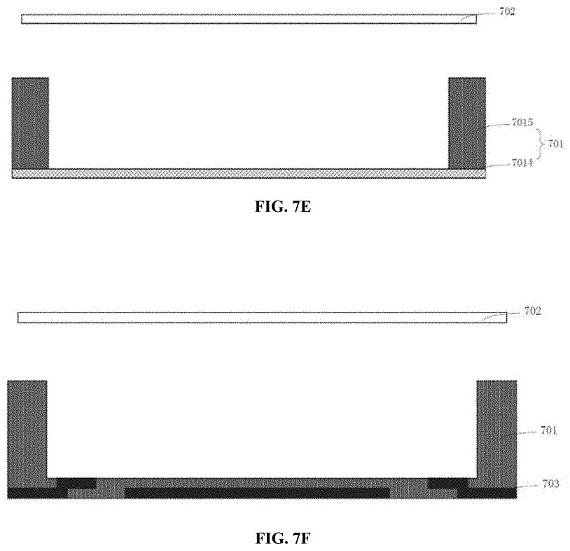

In one embodiment of the present disclosure, as shown in FIGS. 7A-7F, a cover 702 has a flat structure, and an area opposite to the laser diode die 305 is transparent. As an example, the entire cover 702 may be transparent.

In another embodiment of the present disclosure, as shown in FIG. 3A, the cover includes a cover body 302 with a window and a light-transmitting plate 303 disposed on the window. The emitted light of the laser diode die 305 can emit through the light-transmitting plate.

In this embodiment, the light-transmitting area in the cover body may be disposed on the top surface or the side surface of the cover body, and the top surface may be disposed opposite to the first surface. More specifically, the top surface may be disposed parallel to the first surface, and the side surface may be disposed perpendicular to the first surface. The emitted light of the laser diode die can emit through the light-transmitting area. For example, the emitted light of the laser diode die can emit through the light-transmitting area in a direction perpendicular or parallel to the first surface. Alternatively, the emitted light of the laser diode die can emit through the light-transmitting area within a certain angle range in a direction substantially perpendicular or parallel to the first surface. The angle range is not limited to a numerical range, and can be adjusted as needed.

In some embodiments, the emitted light of the laser diode die can emit directly through the light-transmitting area; or the emitted light of the laser diode die can be reflected by a reflector and then emitted through the light-transmitting area.

For example, when the emission direction of the emitted light of the laser diode die is perpendicular to the light-transmitting area in the cover, the emitted light of the laser diode die may directly emit through the light-transmitting area. When the emission direction of the emitted light of the laser diode is parallel to the light-transmitting area in the cover, a reflector may be provided, and the light emitted from the laser diode die may be reflected by the reflector and then emitted through the light-transmitting area. Based on the above description, there are several implementation methods.

In the first implementation method, as shown in FIG. 3A, the light-transmitting area is disposed on the top surface of the cover body, and disposed in parallel with the first surface. The laser diode die is vertically disposed, and the emitted light of the laser diode die is emitted directly through the light-transmitting area.

In the second implementation method, as shown in FIG. 3E, the light-transmitting area is disposed on the top surface of the cover body, and disposed in parallel with the first surface. The laser diode die is horizontally disposed, and the emitted light of the laser diode die is parallel to the light-transmitting area. At this time, a reflector 311 needs to be disposed on the substrate, and an angle between the crystal plane of the reflector and the horizontal direction is 45°. The light emitted in the horizontal direction can be changed into a reflected light in the vertical direction by the reflector 311, in order to be reflected out through the light-transmitting area.

In the third implementation method, as shown in FIGS. 3C and 3D, the light-transmitting area is disposed on the side surface of the cover, and is perpendicular to the first surface. The laser diode die is horizontally disposed, and the emitted light of the laser diode die is emitted directly to the light-transmitting area.

In order to better make the emitted light of the laser diode die directly face the light-transmitting area, a heat sink or a support structure may be disposed on the substrate to adjust the height of the laser diode die.

In the fourth implementation method, the light-transmitting area may be disposed on the side surface of the cover and disposed in parallel with the first surface. The laser diode die may be vertically disposed, and the emitted light of the laser diode die may be parallel to the light-transmitting area. At this time, a reflector needs to be disposed in the accommodation space formed by the substrate and the cover, for example, the reflector may be disposed on the top surface of the cover. The angle between the crystal plane of the reflector and the horizontal direction may be at 45°. The light emitted in the vertical direction can be changed into a reflected light in the horizontal direction by the reflector, in order to be reflected out through the light-transmitting area.

It should be noted that the above embodiments are merely examples. The technical solutions of the present disclosure may also include modifications of the embodiments described above and other achievable embodiments, which are not limited to the examples, and will not be listed here.

In some embodiments, the packaged module may further include a first heat sink 304 and a second heat sink 306 respectively and oppositely disposed on the first surface and the second surface of the laser diode die. The first surface and the second surface of the laser diode die may be surfaces other than the exist surface of the laser diode die. The first sink 304 and the second heat sink 306 may also play a good role in heat dissipation to dissipate the heat on the laser diode die. Through this setting, the heat of the laser diode die can be dissipated as soon as possible to avoid burning the laser diode die, which further improves the reliability of the packaged module.

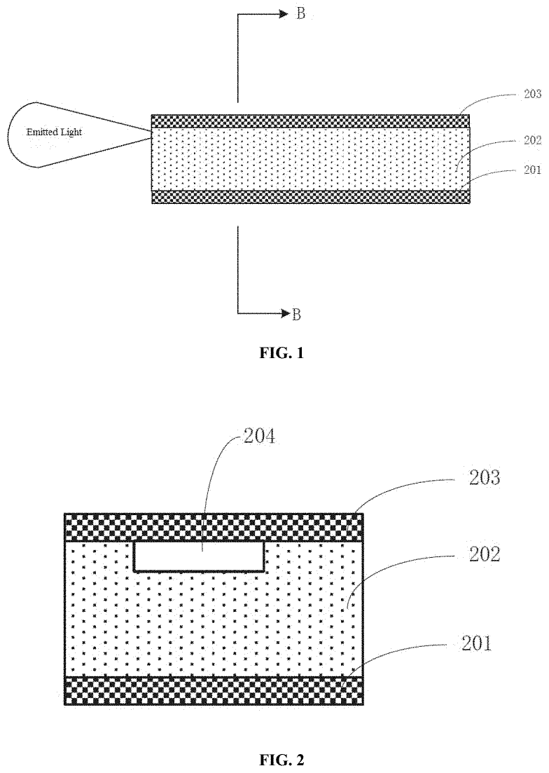

The structure of the laser diode die is shown in FIGS. 1 and 2, where FIG. 1 is a schematic diagram of a structure of a laser diode in a laser diode module according to an embodiment of the present disclosure, and FIG. 2 is a cross-sectional view of the laser diode of FIG. 1 along a B-B direction. The laser diode die includes a first electrode 201 and a second electrode 203. The first heat sink is disposed on the first surface of the laser diode die where the first electrode is located. The second heat sink is disposed on the second surface of the laser diode die where the second electrode is located.

In some other embodiments, as shown in FIG. 3D, the first heat sink and the second heat sink can be omitted, and the first electrode of the laser diode die 305 can be directly mounted on the first surface. At the same time, the second electrode of the laser diode die 305 may be connected to the first surface of the substrate through a wire 310.

In some other embodiments, any one of the first heat sink and the second heat sink can also be retained. For example, as shown in FIGS. 3C and 3E, only the first heat sink is retained, and the first heat sink is flatly disposed on the first surface. The first electrode of the laser diode die 305 is directly attached to the first heat sink, and the second electrode of the laser diode die 305 is connected to the substrate through the wire 310.

In some embodiments, the first heat sink and the second heat sink may include metal or metalized material.

The metal material may include common metals, such as copper, and the metalized material may include a semiconductor material coated with a metal on the surface, such as a silicon plate coated with aluminum.

In one embodiment of the present disclosure, both the first heat sink and the second heat sink may be made of copper material to achieve better heat dissipation effect.

In some embodiments, the first heat sink and the first electrode may be glued by a conductive adhesive; and the second heat sink and the second electrode may also be glued by a conductive adhesive.

The conductive adhesive may include materials such as a conductive glue, a silver paste, or a solder paste, but the present disclosure is not limited thereto.

In the embodiment of the present disclosure, the first heat sink and the second heat sink can be disposed on the first electrode and the second electrode, and glued with a conductive material, such that the electrical connection points of the two electrodes of the laser diode can be connected to the two metal heat sinks. The metal heat sinks not only play the role of connection, but also play the role of heat dissipation, which can simplify the preparation process and reduce the process cost.

In some embodiments, the laser diode die, the first heat sink, and the second heat sink may all have a cuboid structure. The first heat sink and the second heat sink may be respectively disposed on the first surface and the second surface of the laser diode die perpendicular to the exit surface.

The shape of the laser diode die may be a cylindrical structure. For example, it can be a cuboid, and it can be a polyhedron, a cylindrical shape, and other suitable shapes, which will not be listed here. The exit surface of the laser diode die may be disposed on the side wall at one end of the cylindrical structure of the laser diode die.

In some embodiments, the laser diode die may have a cuboid structure, the first surface and the second surface may be the upper and lower surfaces of the cuboid structure, and the exit surface of the laser diode die may refer to the side surface of one end of the cuboid structure. As shown in FIG. 1, the exist surface of the laser diode die is the side surface at the left end of the cuboid structure, in which a light-emitting area 204 is disposed under the second electrode, as shown in FIG. 2.

It should be noted that the exit surface may also be the side surface at the right end of the laser diode die, and may also be the front and back of the laser diode die, and is not limited to the above example.

In some embodiments, the first heat sink and the second heat sink may each include a first end and a second end opposite to each other, and the end surface of at least one of the first end of the first heat sink and the first end of the second heat sink may be lower than the exit surface.

For example, the end surface of the second heat sink 306 may be retracted by a certain distance from the exit surface of the laser diode die, in order to reduce the light shielding rate of the laser diode die, such that the emitted light of the laser diode die may be better emitted. The end surface of the laser diode die exit surface of the first heat sink may protrude for a certain distance to facilitate cutting. In addition, increasing the volume of the second heat since can also improve the heat dissipation efficiency.

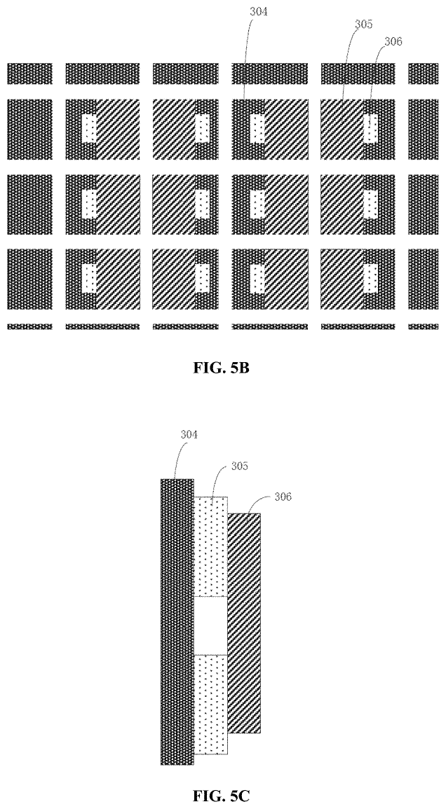

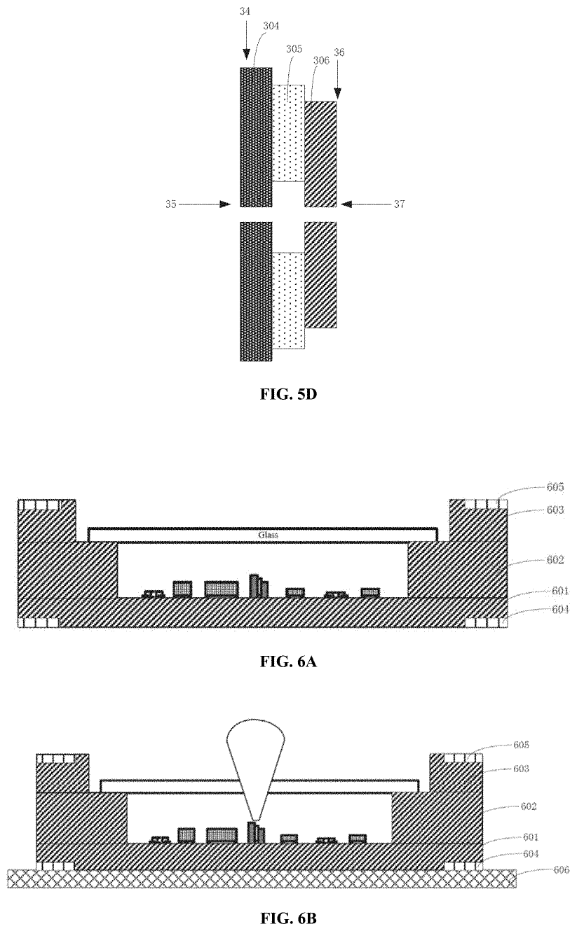

More specifically, as shown in FIG. 5D, the first heat sink 304 includes a first end 34 and a second end 35 opposed to each other, and the second heat sink 306 includes a first end 36 and a second end 37 opposed to each other. The heights of the first end 34 of the first heat sink 304, the exit surface of the laser diode, and the first end 36 of the second heat sink 306 relative to the first surface of the substrate are successively reduced and have a stepped structure.

In some embodiments, as shown in FIG. 3A, the second end 35 of the first heat sink 304 and the second end 37 of the second heat sink 306 are disposed flush and vertically mounted on the first surface of the substrate.

In some embodiments, the bottom surface of the laser diode die opposite to the exit surface may be suspended between the first heat sink and the second heat sink, and may have a predetermined distance from the first surface of the substrate.

In some embodiments, the second end 35 of the first heat sink 304 and the second end 37 of the second heat sink 306 may be attached to the first surface of the substrate through a soldering material 37.

The soldering material 37 may be a glue made of conductive material, such as a silver paste or a solder paste, but the present disclosure is not limited thereto.

A preparation method of the laser diode die will be described below with reference to FIG. 5A-5D. It should be noted that the method is only an example and is not limited to this method. Other methods commonly used in the field can be applied to the present disclosure, and will not be repeated here.

A method for preparing the laser diode die may include providing a whole piece of the first heat sink 304, mounting the whole of the first heat sink 304 on a packaging fixture, and mounting the laser diode die 305. As shown in FIG. 5A, the laser diode die 305 are mounted at intervals to form a laser diode die array of several rows and several columns. Then the second heat sink 306 may be attached to the laser diode die, where the number of the second heat sink 306 may be one. For example, a second heat sink 306 may be mounted on each laser diode die. Then cut, where FIG. 5A illustrates a laser diode die including the heat sink obtained after cutting. At the end, a sandwich structure of the first heat sink, the laser diode die, and the second heat sink may be flipped by 90° using a flip chip, such that the sandwich structure may be erected and attached on the package substrate.

In some embodiments, another method for preparing the laser diode die may include providing a whole piece of the first heat sink 304, mounting the whole of the first heat sink 304 on a packaging fixture, and mounting the laser diode die 305. Every two laser diode dies may be a group as a repeating unit. The repeating unit may be used to form an array of rows and columns on the first heat sink. As shown in FIG. 5B, in each group of repeating units, the two laser diode dies are disposed at intervals and the exit surfaces of the laser diodes are far away from each other, and both are disposed facing outside. FIG. 5C is a schematic structural view of the laser diode included in the laser diode module before cutting according to an embodiment of the present disclosure. Next, the second heat sink 306 may be attached to the laser diode die, where the second heat sink 306 may have a strip structure, for example, extending in the direction of the columns. Each second heat sink 306 may cover a group (i.e., two laser diode dies) of the laser diode dies and expose the exit surface of the laser diode dies. For example, one end of the exit surface of each laser diode die may be exposed. Then, cutting is performed, where FIG. 5D is the laser diode die including the heat sink obtained after cutting. This method can ensure that the second end of the first heat sink and the second heat sink are flush with the end surface bonded to the substrate, and the emitted light of the laser diode die can be emitted vertically. At the end, a sandwich structure of the first heat sink, the laser diode die, and the second heat sink may be flipped by 90° using a flip chip, such that the sandwich structure may be erected and attached on the package substrate.

For the materials of the first heat sink and the second heat sink, as well as the bonding methods of the first heat sink, the second heat sink, and the laser diode, reference may be made to the previous description, and will not be further described here.

In this embodiment, a plurality of dummy dies may be disposed between the first heat sink and the second heat sink on the outside of three other sides of the laser diode die except the exit surface. Since the height of the second heat sink 306 is lower than the height of the laser diode die, the end surface of the second heat sink 306 may be retracted a certain distance from the exit surface of the laser diode die. Therefore, the bonding area between the second heat sink 306 and the laser diode die may be relatively small, and may be separated during the cutting process. By using the dummy dies, the separation may be prevented.

For example, a plurality of dummy dies with the same thickness as the laser diode die may be disposed between the first heat sink and the second heat sink below the bottom end of the laser diode die to improve the structural strength, thereby ensuring that the first heat sink or the second heat sink will not be separated from the laser diode die during the cutting process.

In some embodiments, the dummy dies may be made of glass or other insulators, but the material is not limited thereto.

In addition, other devices may be disposed on the substrate. As shown in FIG. 3A, FET devices or other types of switching devices, or switching device drive chips, needed resistors and capacitors 308b, and devices such as surface-mount technology integrated circuit (SMT IC) can be mounted on the substrate through conductive materials, such as conductive adhesives (including but not limited to solder paste), through surface mount technology (SMT).

The laser diode module of the present disclosure can reduce the distributed inductance existing in the conventional direct-insertion packaging method and improve the intensity of the laser emission. In addition, the ranging device implemented based on the packaged module based on the embodiment of the present disclosure can increase the transmission power and quickly respond to the fast pulse drive signal, thereby improving the reliability and accuracy, reducing the production cost and complexity, and improving the production efficiency.

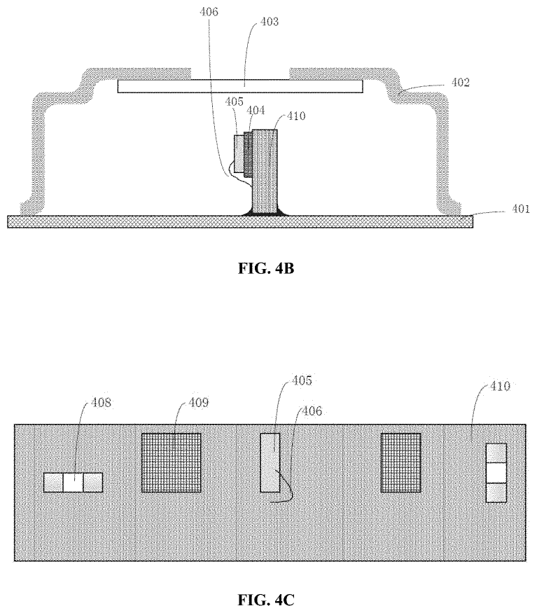

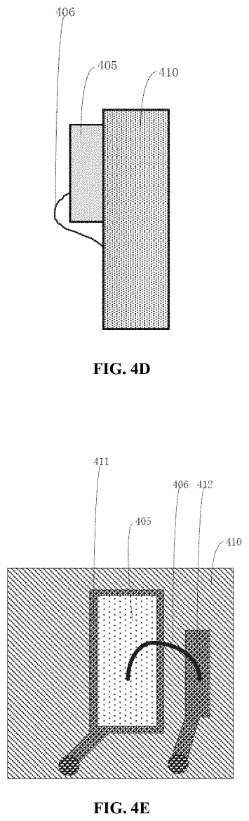

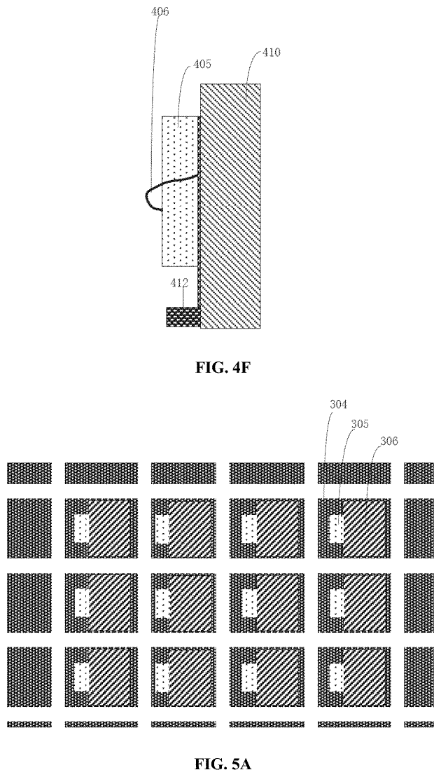

Another embodiment of the present disclosure will be further described below with reference to FIGS. 4A-4F. In this embodiment, the structure of a laser diode die 405, the selection of the material of a third heat sink 404, the connection method between the laser diode die and the third heat sink 404 (for example, through a conductive material, such as a conductive glue 407 (including but not limited to solder paste)), a substrate 401, the selection of the cover (including a cover body 402 and a light-transmitting plate 403) and the connection between the two, the resistors and capacitors 408, the SMT IC, and other devices, reference may be made to the previous embodiment, and will not be further described here. The difference between this embodiment and the previous embodiment is that the packaged module further includes a carrier 410.

As shown in FIGS. 4A-4F, the carrier 410 is vertically mounted on the first surface of the substrate 401, where the laser diode die 405 and the driver chip are mounted on the carrier. The following is a description for the case where the carrier is used.

In some embodiments, the packaged module may further include a driver chip for controlling the emission of the laser diode die, and the driver chip may be mounted on the carrier.

In this embodiment, the driver chip 309 that controls the emission of the laser diode die and the laser diode die are both mounted on the carrier 410. By using this setting, the inductance between the in-line laser diode and the driving circuit adjacent to the laser diode in the conventional in-line package can be eliminated, including the distributed inductance on the line. As such, the distributed inductance of the packaged module can be reduced, and high-power emission and narrow pulse lase driving can be realized.

In some embodiments, the packaged module may further include a third heat sink 404. As shown in FIG. 4A, the third heat sink 404 is mounted on the carrier 410, where the laser diode die 405 is mounted on the third heat sink.

In some embodiments, the material of the third heat sink may include a metal material or a metalized material. The metal material may include copper, and the metalized material may include a metalized ceramic plate or a metalized silicon plate.

Further, the laser diode die may include a first electrode and a second electrode disposed opposite to each other, and the structure may be the same as that of the previous embodiment, as shown in FIGS. 1 and 2. The first surface where the first electrode is located and the second surface where the second electrode is located may be surfaces other than the exit surface of the laser diode die, and the first electrode may be mounted on the third heat sink 404.

As shown in FIG. 4B, the second electrode is electrically connected to the carrier through an electrical connection line 406. In particular, FIG. 4B is a cross-sectional view of the laser diode module of FIG. 4A along the A-A direction.

The carrier can be mounted on the substrate through SMT. The specific mounting method can be the commonly used method in the field, such as using a solder paste to mount the substrate through SMT, which will not be described in detail here.

In some embodiments, the second surface of the substrate may be mounted on a circuit board.

In some embodiments, in one embodiment of the present disclosure, the method for preparing a packaging module including the carrier may include the following processes.

(a) mounting a SMT IC 409 on the vertical carrier 410 through SMT.

(b) mounting the third heat sink 404 (e.g., a copper heat sink) on the vertical carrier in a die bond manner.

(c) mounting the laser diode die 405 on the vertical carrier 410 with conductive glue in a die bond manner, for example, mounting the first electrode of the laser diode die on the vertical carrier 410.

(d) connecting the second electrode of the laser diode die 405 to the vertical carrier using a wire (e.g., a gold wire) through die bond.

(e) placing the vertical carrier SMT on the substrate 401 and ensure that the exit surface of the laser diode die 405 is facing a package window.

(f) parallel to the processes (a) to (e) above, producing the cover body 402 with a window (such as a U-shaped metal shell), cutting the light-transmitting plate 403 (such as glass), and bonding the light-transmitting plate 403 from the inside of the cover body 402 to the window.

(g) bonding the cover body 402 with the light-transmitting plate 403 on the substrate through SMT.

(h) marking, cutting, and testing.

It should be noted that the method described above is merely an example and the present disclosure is not limited to this method. Those skilled in the art can choose other commonly used methods for packaging, which will not be described in detail here.

In some embodiments, the carrier may include a metalized ceramic board. In one embodiment of the present disclosure, the carrier may be an aluminum nitride ceramic plate. At this time, the carrier 410 may also function as a heat sink. As shown in FIGS. 4C and 4D, where FIG. 4C is a top view of the laser diode module according to an embodiment of the present disclosure, and FIG. 4D is a cross-sectional view of the laser diode module of FIG. 4C. In this embodiment, the third heat sink can be omitted, and the driver chip 409 and the laser diode die can be directly mounted on the carrier 410, thereby simplifying the manufacturing process and achieving good heat dissipation effect.

In some other embodiments, the carrier may include a metalized silicon plate. The metalized silicon plate may include a metal film 411 formed on the surface of a partial area of the silicon plate for electrical connection. At this time, the carrier 410 may also function as a heat sink. As shown in FIGS. 4E and 4F, where FIG. 4E is a top view of the laser diode module according to another embodiment of the present disclosure, and FIG. 4F is a side view of the laser diode module according to yet another embodiment of the present disclosure. In this embodiment, the third heat sink can be omitted, and the driver chip 409 and the laser diode die can be directly mounted on the carrier 410, thereby simplifying the manufacturing process and achieving good heat dissipation effect. In this embodiment, a metal pillar 412, such as a copper pillar, may also be disposed on the silicon plate for electrically connecting the carrier and the substrate.

As described in the previous embodiments, the laser dies can be directly mounted on the substrate and the laser dies can be mounted on the carrier and then mounted on the substrate. The combination of the packaging method, the substrate, and the cover in the previous embodiments will be described below with reference to the accompanying drawings. It should be noted that the combination of the packaging method, the substrate, and the cover is not limited to the listed example, and modifications of the example are also included in the protection scope of the appended claims.

The packaging method of the present disclosure will be further described below with reference to the accompanying drawings. The packaging method in the present disclosure may include the following processes.

1. Forming a laser diode and a driver chip on the first surface of the substrate and mounting the second surface of the substrate on the circuit board, as shown in FIGS. 3A-3E, 4A-4B, and 6A-6B.

The method of forming the laser diode and the driver chip on the first surface of the substrate may include directly mounting the laser diode and the driver chip on the first surface of the substrate, or mounting the laser diode and the driver chip on the first surface of the substrate through the carrier described in the previous embodiments.

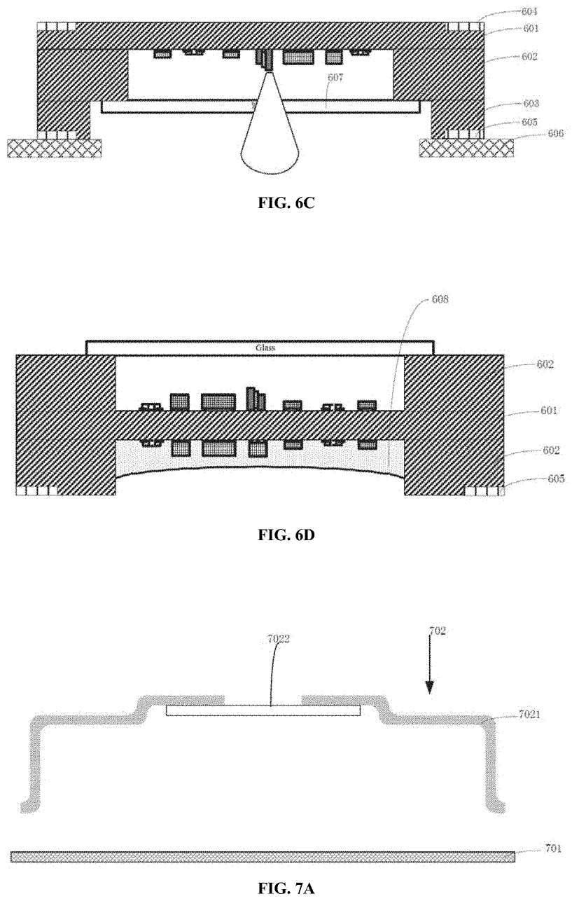

2. Forming the laser diode and the driver chip on the first surface of the substrate, and mounting the first surface of the substrate on the circuit board, as shown in FIG. 6C.

In this embodiment, the first surface including the laser diode and the driver chip may be mounted on the circuit board. In order to ensure that the emitted light of the laser diode can be emitted normally during the packaging process, the shape of the substrate and cover need to be improved, such that the side where the laser diode and the driver chip are formed may be used for packaging.

More specifically, in one embodiment of the present disclosure, as shown in FIG. 6C, the first surface of the substrate has a groove structure, and the first surface of the substrate is mounted on a circuit board with a hole through an open end of the groove structure. The hole is disposed opposite to the emission direction of the emitted light of the laser diode die.

As an implementation manner, as shown in FIG. 6C, the substrate includes a first sub-substrate 601, a second sub-substrate 602, and a third sub-substrate 603 that are sequentially stacked. The first sub-substrate 601 has a flat plate structure. The second sub-substrate 602 has a ring structure, and a first hole is formed in the second sub-substrate. The third sub-substrate 603 has a ring structure, and a second hole is formed in the second sub-substrate. The size of the second hole is larger than the size of the first hole to expose a part of the second sub-substrate 602, and a cover 607 is disposed on the exposed second sub-substrate 602. The cover 607 may be a fully transparent plate-like structure to form an accommodation space between the cover and the first sub-substrate, and mount the third sub-substrate on a circuit board 606. A plurality of first pins 605 are disposed at the edge of the third sub-substrate, and the third sub-substrate is connected to the circuit board 606 through the plurality of first pins 605.

The first sub-substrate 601, the second sub-substrate 602, and the third sub-substrate 603 may be formed separately or all at once through an injection molding process, and is not limited to a specific manner. In addition, the substrate having the groove structure can be formed in similar manner.

A hole exposing an area where the device is formed on the substrate, especially the area where the laser diode die is positioned, may be disposed on the circuit board 606 to ensure that the light emitted by the laser diode die can be emitted normally.

3. Forming the laser diode die and the driver chip on the first surface of the substrate and mounting the first surface of the substrate on a circuit board, while mounting the second surface of the substrate on another circuit board.

More specifically, in one embodiment of the present disclosure, as shown in FIG. 6C, the first surface of the substrate has a groove structure, and the first surface of the substrate is mounted on a circuit board with a hole through an open end of the groove structure. The hole is disposed opposite to the emission direction of the emitted light of the laser diode die.

As an implementation manner, as shown in FIG. 6C, the substrate includes the first sub-substrate 601, the second sub-substrate 602, and the third sub-substrate 603 that are sequentially stacked. The first sub-substrate 601 has a flat plate structure. The second sub-substrate 602 has a ring structure, and a first hole is formed in the second sub-substrate. The third sub-substrate 603 has a ring structure, and a second hole is formed in the second sub-substrate. The size of the second hole is larger than the size of the first hole to expose a part of the second sub-substrate 602, and a cover 607 is disposed on the exposed second sub-substrate 602. The cover 607 may be a fully transparent plate-like structure to form an accommodation space between the cover and the first sub-substrate, and mount the third sub-substrate on a circuit board 606 and the first sub-substrate on another circuit board (not shown in FIG. 6C) at the same time. A plurality of first pins 605 are disposed on the edge of the third sub-substrate, and the third sub-substrate is connected to the circuit board 606 through the plurality of first pins 605. A plurality of second pins 604 are disposed at the edge of the first sub-substrate, and the first sub-substrate 601 is connected to another circuit board through the plurality of second pins 604.

4. Forming the laser diode on the first surface of the substrate, and at least a part of the driving chips is disposed on the second surface of the substrate. Subsequently, mounting the second surface of the substrate on the circuit board, as shown in FIG. 6D.

More specifically, a part of the driving chips may be attached to the first surface and another part of the driving chips may be mounted on the second surface. Alternatively, all driving chips may be completely mounted on the second surface of the substrate, as shown in FIG. 6D.

In some embodiments, the substrate includes the first sub-substrate 601, and the second sub-substrate 602 may be formed on both the first surface and the second surface of the first sub-substrate. The first sub-substrate 601 may have a flat plate structure. The second sub-substrate 602 may have a ring structure, and a first hole may be formed on the second sub-substrate to expose a part of the first sub-substrate for forming devices. Subsequently, the cover 607 may be disposed on the second sub-substrate 602, which can be disposed on the second sub-substrate 602 on the first surface or the second sub-substrate 602 on the second surface.

As an implementation manner, as shown in FIG. 6D, the cover 607 is disposed on the second sub-substrate 602 on the first surface. The cover 607 may be a fully transparent plate-like structure to form an accommodation space between the cover and the first sub-substrate. At the same time, in order to prevent the devices on the second surface of the first sub-substrate from falling, a light-transmitting glue 608 covering the driver chip may be disposed on the second surface of the first sub-substrate.

In some embodiments, a plurality of first pins 605 are disposed at the edge of the second sub-substrate 602 on the second surface of the first sub-substrate, and is connected to the circuit board through the plurality of first pins 605 (not shown in FIG. 6D).

As another implementation manner, a plurality of first pins 605 are disposed at the edge of the second sub-substrate 602 on the second surface of the first sub-substrate. After the plurality of first pins 605 are connected to the circuit board (not shown FIG. 6D), a plurality of second pins may be disposed at the edge of the second sub-substrate on the first surface of the first sub-substrate, and connect the first surface of the first sub-substrate and the circuit board through the plurality of second pins (not shown in FIG. 6D). Therefore, the first surface and the second surface of the first sub-substrate can be mounted on the circuit board at the same time.

A hole exposing an area where the device is formed on the substrate, especially the area where the laser diode die is positioned, may be disposed on the circuit board to ensure that the light emitted by the laser diode die can be emitted normally.

It should be noted that the packing method described above is merely an example, and the packaging method of the present disclosure is not limited to the above example. Various modifications of the above example can also be applied to the present disclosure. For example, the number of sub-substrates formed on the first surface and/or the second surface, the size of the sub-substrates, the shape of the holes, etc. can all be selected based on actual needs. In another example, the number of substrates formed on the surface and the second surface and the size of the sub-substrates may be the same, and the shapes of the grooves formed on the first surface and the second surface may be completely symmetrical. As an alternative embodiment, the number of substrates formed on the first surface and the second surface and the size of the sub-substrates may not be the same, and they can be designed based on actual needs, which will not be listed here.

Examples of substrate and cover are described below.

### 1. Material of the Substrate

The substrates described in the present disclosure may be selected as printed circuit board (PCB) substrates, ceramic substrates, pre-mold substrates, etc.

The PCB is made of different components and a variety of complex process technologies, etc. The structure of the PCB may include a single-layer structure, a double-layer structure, and a multi-layer structure, and the production methods of different layer structures are different.

In some embodiments, the PCB may be mainly composed of pads, via, mounting holes, wires, components, connectors, filling, electrical boundaries, etc.

Further, the common layer structures of PCBs include three types, namely the single-layer PCB, the double-layer PCB, and the multi-layer PCB. The specific structures will be described in detail below.

In the single-layer PCB, one side of the circuit board includes copper, while the other side of the circuit board does not include copper. Generally, components are disposed on the side without copper, and the side with copper is mainly used for wiring and welding.

In the double-layer PCB, both sides of the circuit board include copper. Generally, one side of the double-layer PCB is called the top layer, and the other side is called the bottom layer. The top layer is generally used as a component disposing surface, and the bottom is used as a components welding surface.

In the multi-layer PCB, the circuit board includes multiple working layers. In addition to the top and bottom layers, the circuit board also includes several intermediate layers. Generally, the intermediate layer can be used as a wire layer, signal layer, power layer, ground layer, etc. The layers are insulated from each other, and the connection between the layers is generally achieved through holes.

The PCB may include many types of working layers, such as signal layer, protective layer, silk screen layer, internal layer, etc., which will not be described in detail here.

In addition, the substrate described in the present disclosure can also be a ceramic substrate. Ceramic substrate may be referred to a special process board in which copper foil is directly bonded to alumina (Al₂O₃) or aluminum nitride (AlN) ceramic substrate surface (single-sided or double-sided) at high temperature. The formed ultra-thin composite substrate has excellent electrical insulation properties, high thermal conductivity, excellent solderability and high adhesion strength. In addition, the substrate can be etched into various pattern a like a PCB board, and has a great current-carrying capacity.

Further, as shown in FIG. 7F, a substrate 701 may be a pre-mold substrate. The pre-mold substrate includes injection molded wires and a plurality of pins 703. The injection molded wires can be embedded in the main structure of the substrate 701. The plurality of pins 703 are positioned on the surface of the main structure of the substrate 701, such as the inner surface and/or the outer surface, thereby realizing the electrical connection between the substrate and the laser diode die, the driving chip, and the circuit board, respectively.

The preparation method of the pre-mold substrate can be formed through a conventional injection process, planer excavation, and mold embossing, which will not be described in detail here.

The injection material of the pre-mold substrate can be a conventional material, such as a thermally conductive plastic material, etc. but is not limited to a certain type of material. The shape of the pre-mold substrate is limited to the injection frame and is not limited to a certain type of injection frame.

In one embodiment, a PCB substrate 7014 is first disposed in the injection molding frame on the substrate, and then an annular groove structure 7015 is formed on the PCB substrate 7014 by injection molding, as shown in FIG. 7E.

Alternatively, the injection molded wires and the pins 703 can be disposed in the injection frame, and then injection mold the injection frame to obtain the structure as shown in FIG. 7F.

### 2. Shape of the Substrate

The shape of the substrate may be a plate. As shown in FIGS. 7A and 7B, the substrate 701 has a flat plate structure.

In some embodiments, as shown in FIG. 7D, the overall structure of the substrate may be in the shape of a groove. For example, the substrate 701 may include a first sub-substrate 7011, a second sub-substrate 7012, and a third sub-substrate 7013 that are sequentially stacked. The first sub-substrate 7011 may have a flat plate structure. The second sub-substrate 7012 may have a ring structure, and a first hole may be formed in the second sub-substrate. The third sub-substrate 7013 may have a ring structure, and a second hole may be formed in the second sub-substrate. The size of the second hole is larger than the size of the first hole to expose a part of the second sub-substrate 7012. Then a cover 702 may be disposed on the exposed second sub-substrate 7012. The cover 702 may be a fully transparent plate-like structure to form an accommodation space between the cover and the first sub-substrate. A plurality of first pins 703 are disposed on the edge of the third sub-substrate, and the third sub-substrate is connected to the circuit board through the plurality of first pins 703. A plurality of second pins 704 are disposed at the edge of the first sub-substrate, and the first sub-substrate is connected to another circuit board through the plurality of second pins 604.

In some embodiments, the shape can also be as shown in FIG. 7C. The difference from FIG. 7D is that the number of the sub-substrate is two, and the others can be completely the same, which will not be repeated here.

### 3. Shape and Material of the Cover

In some embodiments, as shown in FIGS. 7A and 7B, the shape of the cover 702 may be a U-shaped cover body to be buckled on the substrate 701.

In this embodiment, the cover 702 includes a U-shaped cover body 7021 with a window, and a light-transmitting plate 7022 disposed on the window. The emitted light of the laser diode die can be emitted through the light-transmitting plate.

In some embodiments, the light-transmitting plate 7022 may be made of commonly used light-transmitting materials, such as glass. The glass needs to have high passability to the wavelength of the laser light emitted by the laser diode die.

In some embodiments, as shown in FIGS. 7C-7F, the cover is a plate-like structure with complete light transmissibility. The plate-shaped structure may be made of commonly used light-transmitting materials, such as glass, which needs to have high passability to the wavelength of the laser light emitted by the laser diode die.

For example, in a specific embodiment of the present disclosure, the outer cover is a metal shell with a glass window, and the substrate is a PCB substrate, as shown in FIG. 7A. Alternatively, the outer cover is a pre-mold housing with a glass window, and the substrate is a PCB substrate, as shown in FIG. 7B. Alternatively, the outer cover is a glass plate, and the substrate is a double-layer ceramic substrate, as shown in FIG. 7C. Alternatively, the outer cover is a glass plate, the substrate is a triple-layer ceramic substrate, and a plurality of pins are disposed in both the first layer and the third layer of the ceramic substrate, as shown in FIG. 7D. Alternatively, the outer cover is a glass plate, the substrate is a substrate pre-injected on a PCB board, as shown in FIG. 7E. Alternatively, the outer cover is a glass plate, the substrate is a pre-mold substrate, where the pre-mold substrate includes injection molded wires and pins 703 to realize electrical connections between the substrate and the laser diode die, the driving chip, and the circuit board respectively, as shown in FIG. 7F.

In view of the above, the material and shape of the substrate and the material and shape of the cover can be combined arbitrarily without contradicting each other to obtain a variety of implementations in which the substrate and the cover can be combined. Of course, the material and shape of the substrate and the material and shape of the cover are not limited to the above examples, and may also be variations of the above examples and other examples commonly used in the art.

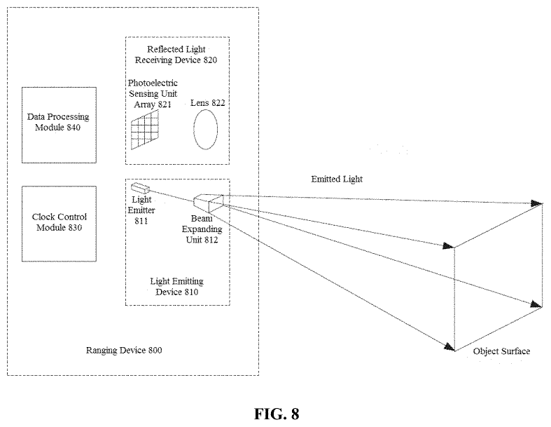

As shown in FIG. 8, an embodiment of the present disclosure further provides a ranging device 800 including a light emitting device 810 and a reflected light receiving device 820. The light emitting device 810 may include the laser diode module described in the previous embodiments for emitting light signals, and the light emitted by the light emitting device 810 may cover the field of view (FOV) of the ranging device 800. The reflected light receiving device 820 can be used to receive the reflected light generated after the light emitted by the light emitting device 810 encounters an object to be measure, and calculate the distance of the ranging device 800 from the object to be measured. The light emitting device 810 and its working principle will be described below with reference to FIG. 8.

As shown in FIG. 8, the light emitting device 810 includes a light emitter 811 and a light beam expanding unit 812. The light emitter 811 can be used to emit light, and the light beam expanding unit 812 can be used to perform at least one of the processes of collimation, beam expansion, homogenization, and FOV expansion on the light emitted by the light emitter 811. The light emitted by the light emitter 811 passes through at least one of the collimation, beam expansion, homogenization, and FOV expansion of the light beam expanding unit 812, such that the emitted light becomes divergent and evenly distributed, which can cover a certain two-dimensional angle in a scene. As shown in FIG. 8, the emitted light can cover at least a part of the surface of the object to be measured.

In some embodiments, the light emitter 811 may be a laser diode. For the wavelength of the light emitted by the light emitter 811, in one example, light with a wavelength between 895 nanometers and 915 nanometers can be selected. For example, light with a wavelength of 905 nanometers may be selected. In another example, light with a wavelength between 1540 nanometers and 1560 nanometers can be selected. For example, light with a wavelength of 1550 nanometers may be selected. In other examples, other suitable wavelengths of lights may also be selected based on the application scenarios and various needs.

In some embodiments, the light beam expanding unit 812 may be implemented by a one-stage or multi-stage beam expansion system. The light beam expansion process can be reflective or transmissive, or a combination of the two. In one example, a holographic filter may be used to obtain a large-angle beam composed of multiple sub-beams.

In another example, a laser diode array may also be used to form multiple light beams with laser diodes to obtained lasers similar to the beam expansion (as the VCSEL laser array described above).

In yet another example, a two-dimensional angle adjustable micro-electromechanical system (MEMS) lens may also be used to reflect the emitted light. By using the MEMS micro-mirror to constantly change the angle between the mirror surface and the light beam, the angle of the reflected light is constantly changing, thereby diverging into a two-dimensional angle to cover the entire surface of the object to be measured.

The ranging device can be used to sense external environment information, such as distance information, angle information, reflection intensity information, speed information, etc. of targets in the environment. More specifically, the ranging device provided in the embodiment of the present disclosure can be applied to a mobile platform, and the ranging device can be mounted on a platform body of the mobile platform. A mobile platform with the ranging device can measure the external environment, such as measuring the distance between the mobile platform and obstacles for obstacle avoidance and other purposes, and external environment for two-dimensional or three-dimensional mapping. In some embodiments, the mobile platform may include at least one of an unmanned aerial vehicle (UAV), a car, and a remote control car. When the ranging device is applied to an UAV, the platform body may be the body of the UAV. When the ranging device is applied to a car, the platform body may be the body of the car. When the ranging device is applied to a remote control car, the platform body may be the body of the remote control car.

Since the light emitted by the light emitter 810 can cover at least a part of the surface or even the entire surface of the object to be measured, correspondingly, the light reflected after reaching the surface of the object, and the reflected light reaching the reflected light receiving device 820 is not a single point, but is distributed in an array.

The reflected light receiving device 820 may include photoelectric sensing unit array 821 and a lens 822. After the light reflected from the surface of the object to be measured reaches the lens 822, based on the principle of lens imaging, it can reach the corresponding photoelectric sensing unit in the photoelectric sensing unit array 821, and then be received by the photoelectric sensing unit, causing the photoelectric response of the photoelectric sensing unit.

Since the light being emitted to the photoelectric sensing unit receiving the reflected light, the light emitter 811 and the photoelectric sensing unit array 821 are controlled by a clock control module (e.g., a clock control module 830 shown in FIG. 8 included in the ranging device 800, or a clock control module outside the ranging device 800) to synchronize them. Therefore, based on the time of flight (TOF) principle, the distance between the point where the reflected light reaches and the ranging device 800 can be obtained.

In addition, since the photoelectric sensing unit is not a single point but a part of the photoelectric sensing unit array 821, the distance information of all points in the field of view of the entire ranging device can be obtained through data processing by a data processing module (e.g., a data processing module 840 shown in FIG. 8 included in the ranging device 800, or a data processing module outside the ranging device 800). The distance information may refer to the point cloud data of the distance to the external environment that the ranging device faces.

Based on the foregoing structure and working principle of the laser diode module based on the embodiments of the present disclosure and the structure and working principle of the ranging device based on the embodiment of the present disclosure, those skilled in the art can understand the structure and working principle of the electronic device based on the embodiment of the present disclosure. For the sake of brevity, the structure and working principle of the electronic device will not be repeated here.

With the development of science and technology, detection and measurement technology is applied in various fields. Lidar is a perception system for the environment, which can acquire the three-dimensional information of the environment, and is no longer confined to the plane perception of the environment such as cameras. The principle is to actively transmit laser pulse signals to the outside, detect the reflected pulse signals, determine the distance of the measured object based on the time difference between the emission and reception, and combine the emission angle information of the light pulse to reconstruct and obtain the three-dimensional depth information.

The present disclosure provides a detection device, which can be used to measure the distance from the detection object to the detection device, and the orientation of the detection object relative to the detection device. In one embodiment, the detection device may include a radar, such as a Lidar. The detection device can detect distance between the detection device and the detection object by measuring the time of light propagation between the device and the detection object, that is, the time-of-flight (TOF).

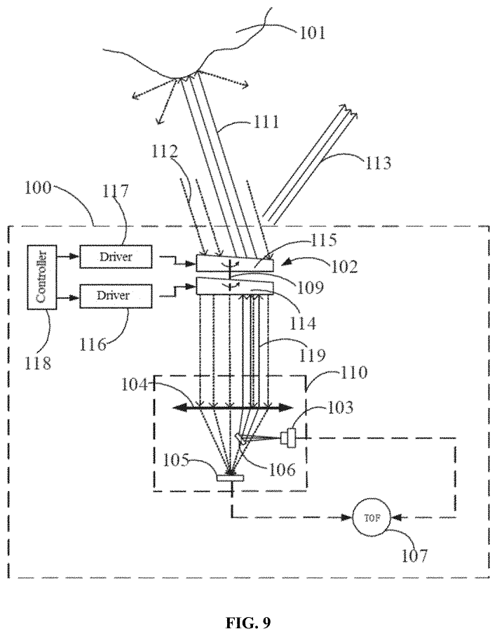

A coaxial optical path can be used in the detection device, that is, the light beam emitted by the detection device and the reflected light beam may share at least a part of the optical path in the detection device. Alternatively, the detection device may also adopt an off-axis optical path, that is, the light beam emitted by the detection device and the reflected light beam may be respectively transmitted along different optical paths in the detection device. FIG. 9 is a schematic diagram of a structure of a detection device according to an embodiment of the present disclosure.

As shown in FIG. 9, a detection device 100 includes an optical transceiver 110, and the optical transceiver 110 includes a light source 103, a collimating element 104, a detector 105, and an optical path changing element 106. The optical transceiver 110 can be used to emit light beams, receive returned light, and convert the returned light into electrical signals. The light source 103 can be used to emit a light beam. In one embodiment, the light source 103 may emit a laser beam. The light source may include the laser diode module described in the previous embodiments. In some embodiments, the laser beam emitted by the light source 103 may be a narrow-bandwidth beam with a wavelength outside the visible light range. The collimating element 104 can be used to collimate the light beam emitted by the light source 103 and collimate the light beam emitted from the light source 103 into parallel light. The collimating element 104 may be a collimating lens or other elements capable of collimating light beams.

The detection device 100 may further include a scanning module 102. The scanning module 102 may be placed on the exit light path of the optical transceiver 110. Further, the scanning module 102 may be used to change the emission direction of a collimated light beam 119 emitted by the collimating element 104 to project to the external environment, and project the returned light to the collimating element 104. The returned light may be collected on the detector 105 via the collimating element 104.

In some embodiments, the scanning module 102 may include one or more optical elements, for example, a lens, a mirror, a prism, a grating, an optical phased array, or any combination of the foregoing optical elements. In some embodiments, multiple optical elements of the scanning module 102 may be rotated around a common axis 109, and each rotating optical element may be used to continuously change the direction of the incident beam. In some embodiments, the multiple optical elements of the scanning module 102 may rotate at different rotation speeds. In some other embodiments, the multiple optical elements of the scanning module 102 may rotate at substantially the same rotation speed.

In some embodiments, the multiple optical elements of the scanning module 102 may also rotate around different axes, or vibration in the same direction, or vibration in different directions, which is not limited here.

In some embodiments, the scanning module 102 may include a first optical element 114 and a driver 116 connected to the first optical element 114. The driver 116 can be used to drive the first optical element 114 around the rotation axis 109, such that the first optical element 114 may change the direction of the collimated light beam 119. The first optical element 114 may project the collimated light beam 119 to different directions. In some embodiments, the angle between the direction of the collimated light beam 119 changed by the first optical element and the rotation axis 109 may change with the rotation of the first optical element 114. In some embodiments, the first optical element 114 may include a pair of opposite non-parallel surfaces through which the collimated light beam 119 passes. In some embodiments, the first optical element 114 may include a wedge-angle prism to collimate the collimated light beam 119 for refracting. In some embodiments, the first optical element 114 may be coated with an anti-reflection coating, and the thickness of the anti-reflection coating may be equal to the wavelength of the light beam emitted by the light source 103, which can increase the intensity of the emitted light beam.

In the embodiment shown in FIG. 1, the scanning module 102 includes a second optical element 115. The second optical element 115 rotates around the rotation axis 109, and the rotation speed of the second optical element 115 may be different from the rotation speed of the first optical element 114. The second optical element 115 may change the direction of the light beam projected by the first optical element 114. In some embodiments, the second optical element 115 may be connected to another driver 117, and the driver 117 may drive the second optical element 115 to rotate. The first optical element 114 and the second optical element 115 may be driven by different drives, such that the rotation speed of the first optical element 114 and the second optical element 115 may be different. As such, the collimated light beam 119 may be projected to different directions in the external environment, and a larger spatial range can be scanned. In some embodiments, a controller 118 can control the drivers 116 and 117 to drive the first optical element 114 and the second optical element 115, respectively. The rotation speeds of the first optical element 114 and the second optical element 115 may be determined based on the area and pattern expected to be scanned in actual applications. The drivers 116 and 117 may include motors or other driving devices.

In some embodiments, the second optical element 115 may include a pair of opposite non-parallel surfaces through which the light beam passes. In some embodiments, the second optical element 115 may include a wedge-angle prism. In some embodiments, the second optical element 115 may be coated with an anti-reflection coating, which can increase the intensity of the emitted light beam.

The rotation of the scanning module 102 can project light to different directions, such as directions 111 ad 113, thereby scanning the space around the detection device 100. When the light 111 projected by the scanning module 102 hits the detection object 101, a part of the light may be reflected by the detection object 101 to the detection device 100 in a direction opposite to the projected light 111. The scanning module 102 can receive a returned light 112 reflected by the detection object 101, and project the returned light 112 to the collimating element 104.

The collimating element 104 may converge at least a part of the returned light 112 reflected by the detection object 101. In some embodiments, an anti-reflection coating may be coated on the collimating element 104 to increase the intensity of the emitted light beam. The detector 105 and the light source 103 may be disposed on the same side of the collimating element 104, and the detector 105 may be used to covert at least a part of the returned light passing through the collimating element 104 into an electrical signal. In some embodiments, the detector 105 may include an avalanche photodiode. The avalanche photodiode is a highly sensitive semiconductor device that can convert optical signals into electrical signals using the photocurrent effect.

In some embodiments, the detection device may include a measuring circuit, such as a TOF unit 107, which can be used to measure TOF to measure the distance of the detection object 101. For example, the TOF unit 107 can calculate the distance by using the formula t=2D/c, where D may be the distance between the detection device and the detection object, c may be the speed of light, and t may be the total time it takes for light to project from the detection device to the detection object and return form the detection object to the detection device. The detection device 100 can determine the time t based on the time different between the light emitted by the light source 103 and the returned light received by the detector 105, and then the distance D can be determined. The detection device 100 can also detect the position of the detection object 101 relative to the detection device 100. The distance and orientation detected by the detection device 100 can be used for remote sensing, obstacle avoidance, surveying and mapping, modeling, navigation, and the like,

In some embodiments, the light source may include a laser diode through which nanosecond laser light can be emitted. For example, the laser pulse emitted by the light source 103 may last 10 ns, and the pulse duration of the returned light detected by the detector 105 may be the same as the duration of the emitted laser pulse. Further, the laser pulse receiving time can be determined. For example, the laser pulse receiving time can be determined by detecting the rising edge time and/or the falling edge time of the electrical signal pulse. In some embodiments, the electrical signal can be amplified in multiple stages. As such, the detection device 100 can calculate the TOF using the pulse receiving time information and the pulse sending time information, thereby determining the distance between the detection object 101 and the detection device 100.

Although the exemplary embodiments have been described herein with reference to the drawings, and it should be understood that the above-described exemplary embodiments are merely exemplary, and are not intended to limit the scope of the present disclosure. Those skilled in the art may make various changes and modifications therein without departing from the scope and spirit of the present disclosure. All these changes and modifications are intended to be included within the scope of the present disclosure as claimed in the appended claims.

Those of ordinary skill in the art may appreciate that various units or steps described in the embodiments of the present disclosure may be implemented by electronic hardware or a combination of computer software and electronic hardware. Whether the functions are performed by hardware or software depends on specific applications and design constraints of the technical solution. Those skilled in the art may use different methods to implement the described functions for each particular application. However, such implementation should be included within the scope of the present disclosure.

In the embodiments of the present disclosure, the disclosed device and method may be implemented in other manners. For example, the device embodiments are merely illustrative. For example, the division of the units is only a logic function division. Other divisions may be possible in actual implementation. For example, a plurality of units or components may be combined or integrated to a different system. Some features may be omitted or may not be executed.

Many details are discussed in the specification provided herein. However, it should be understood that the embodiments of the disclosure can be implemented without these specific details. In some examples, the well-known methods, structures, and technologies are not shown in detail so as to avoid an unclear understanding of the description.

Similarly, it should be understood that, in order to simplify the disclosure and to facilitate the understanding of one or more of various aspects thereof, in the above description of the exemplary embodiments of the disclosure, various features of the disclosure may sometimes be grouped together into a single embodiment, accompanying figure or description thereof. However, the method of this disclosure should not be constructed as follows: the disclosure for which the protection is sought claims more features than those explicitly disclosed in each of claims. More specifically, as reflected in the following claims, the inventive aspect is in that the features therein are less than all features of a single embodiment as disclosed above. Therefore, claims following specific embodiments are definitely incorporated into the specific embodiments, wherein each of claims can be considered as a separate embodiment of the disclosure.

It should be understood by those skilled in the art that except for features that are mutually exclusive, various combinations can be used to combine all the features disclosed in specification (including claims, abstract and accompanying figures) and all the processes or units of any methods or devices as disclosed herein. Unless otherwise definitely stated, each of features disclosed in specification (including claims, abstract and accompanying figures) may be taken place with an alternative feature having same, equivalent, or similar purpose.

In addition, it should be understood by those skilled in the art, although some embodiments as discussed herein comprise some features included in other embodiment rather than other feature, combination of features in different embodiment means that the combination is within a scope of the disclosure and forms the different embodiment. For example, in the claims, any one of the embodiments for which the protection is sought can be used in any combination manner.

Various modules of the present disclosure may be implemented by hardware, software running in one or more processors, or a combination of them. For persons having ordinary skills in the art, some or all of the functions of the modules of the present disclosure may be implemented by a microprocessor or a digital signal processor (DSP). The present disclosure may also be implemented as a device or a program running in a device (e.g., a computer program and a product with computer programs) that perform a part, or all of the methods described herein. Such kind of programs may be stored on a computer readable medium, or may be in a form of one or more signals. Such signals may be downloaded from an Internet website, provided on a carrier signal, or provided in any other forms.

The foregoing descriptions are merely some implementation manners of the present disclosure, but the scope of the present disclosure is not limited thereto. Without departing from the spirit and principles of the present disclosure, any modifications, equivalent substitutions, and improvements, etc. shall fall within the scope of the present disclosure. Thus, the scope of invention should be determined by the appended claims.

What is claimed is:

1. A laser diode module, comprising:
a substrate including a first surface and a second surface opposite to each other;
a cover disposed on the first surface of the substrate, and an accommodation space being formed between the substrate and the cover; and
a laser diode die disposed in the accommodation space.

2. The laser diode module of claim 1, further comprising:
a driver chip disposed in the accommodation space for controlling emission of the laser diode die.

3. The laser diode module of claim 2, wherein:
the laser diode die and the driver chip are mounted on the first surface of the substrate.

4. The laser diode module of claim 1, wherein:
a light-transmitting area is at least partially disposed on the cover, and an emitted light of the laser diode die is emitted through the light-transmitting area.

5. The laser diode module of claim 4, wherein:
the light-transmitting area is disposed on a top surface or a side surface of the cover, the top surface being arranged opposite to the first surface, and the emitted light of the laser diode die is emitted through the light-transmitting area.

6. The laser diode module of claim 5, wherein:
the emitted light of the laser diode is emitted through the light-transmitting area in a direction perpendicular or parallel to the first surface.

7. The laser diode module of claim 4, wherein:
the emitted light of the laser diode is directly emitted through the light-transmitting area;
or the emitted light of the laser diode is reflected by a reflector and then emitted through the light-transmitting area.

8. The laser diode module of claim 4, wherein:
the cover includes a U-shaped cover body with a window and a light-transmitting plate disposed on the window to form the light-transmitting area, and the emitted light of the laser diode is emitted through the light-transmitting area; or
the cover has a plate-like structure with high light transmissibility.

9. The laser diode module of claim 1, further comprising:
a carrier vertically mounted on the first surface of the substrate, wherein the laser diode die and the driver chip are mounted on the carrier.

10. The laser diode module of claim 9, further comprising:
a driver chip disposed in the carrier for controlling emission of the laser diode die.

11. The laser diode module of claim 9, wherein:
the carrier includes a metalized ceramic plate or a metalized silicon plate.

12. The laser diode module of claim 9, further comprising:
a heat sink disposed on the carrier, wherein the laser diode die is mounted on the heat sink.

13. The laser diode module of claim 12, wherein:
the laser diode die includes a first electrode and a second electrode disposed opposite to each other, the first surface where the first electrode is located and the second surface where the second electrode is located being surfaces other than an exit surface of the laser diode die, the first electrode being mounted on the heat sink; and
the second electrode is electrically connected to the carrier through an electrical connection line.

14. The laser diode module of claim 12, wherein:
the material of the heat sink includes a metal material or a metalized material, the metal material including copper, the metalized material including a metalized ceramic plate or a metalized silicon plate.

15. The laser diode module of claim 1, wherein:
the second surface of the substrate is mounted on a circuit board.

16. The laser diode module of claim 2, wherein:
the laser diode die and the driver chip mounted on the first surface of the substrate; and,
the second surface of the substrate is mounted on the circuit board; or,
the first surface of the substrate has a groove structure and the substrate is mounted on the circuit board through an open end of the groove structure.

17. The laser diode module of claim 1, further comprising:
a driver chip mounted on the surface of the substrate for controlling emission of the laser diode die, wherein at least a part of the driver chip is disposed on the second surface of the substrate.

18. The laser diode module of claim 17, wherein:
a light-transmitting glue covering the driver chip is disposed on the second surface of the substrate.

19. The laser diode module of claim 17, wherein:
the second surface of the substrate has a groove structure, at least a part of the driver chip being disposed in the groove structure of the second surface, and the substrate is mounted on the circuit board through an open end of the groove structure.

20. The laser diode module of claim 16, wherein:
the circuit board is a circuit board with holes, and the holes at least partially expose areas on the substrate where functional devices are formed.
